(19) United States
(12) Patent Application Publication
(10) Pub. No.: US 2008/0124895 A1
(43) Pub. Date: May 29, 2008

(54) WAFER BONDING METHOD

(76) Inventors: Shih-Shou Lo, Taoyuan (TW); Chii-Chang Chen, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,105

(22) Filed: Jun. 23, 2006

(51) Int. Cl. H01L 21/30

(52) U.S. Cl. 438/456; 257/E21.214

(57) ABSTRACT

The invention is directed to a wafer bonding method for bonding a first wafer with a second wafer, wherein the first wafer has a first top surface and the second wafer has a second top surface formed thereon and the first wafer bonds with the second wafer in a manner that the first top surface of the first wafer is opposite the second top surface of the second wafer. The wafer bonding method comprises steps of adding a hydroxyl-ion-containing solution between the first top surface and the second top surface and then applying an external pressure on the first wafer and the second wafer. An annealing process is performed.

### BACKGROUND OF THE INVENTION

1. Field of Invention

The present invention relates to a method for semiconductor process. More particularly, the present invention relates to a wafer bonding method.

2. Description of Related Art

Wafer bonding technology has become increasingly important in the packaging and assembly of sophisticated microelectromechanical systems. Many bonding methods have been reported and are employed to form microstructures such as pressure sensors, accelerometers and packing for microsensors. In most of the cases, the hermetic seal and the interface bonding strength are the major concerns and a low-temperature process is essential for bonding a microelectronic wafer to a micromechanical wafer in order to facilitate integration and achieve an increase in device density.

The flexibility of adhesive bonding has already been exploited to demonstrate a semiconductor hollow waveguide formed using an omni-directional reflector (SHOW-ODR) by adhesive wafer binding. The characterization of the SHOW-ODR shows a low propagation loss of 1.7 dB/cm in transverse-electric (TE) and transverse-magnetic (TM) modes. This value exceeds the maximum propagation loss for practical integrated optical applications, 1 dB/cm. Because the expoxy is used to binding two wafers, a 1-μm air gap is generated at the interface between the wafers. The air gap induces significant propagation loss.

### SUMMARY OF THE INVENTION

Accordingly, at least one objective of the present invention is to provide a wafer bonding method capable decreasing the air gap at the interface between the wafers.

At least another objective of the present invention is to provide a method for forming a hollow optical waveguide with a relatively small propagation loss.

To achieve these and other advantages and in accordance with the purpose of the invention, as embodied and broadly described herein, the invention provides a wafer bonding method for bonding a first wafer with a second wafer, wherein the first wafer has a first top surface and the second wafer has a second top surface formed thereon and the first wafer bonds with the second wafer in a manner that the first top surface of the first wafer is opposite the second top surface of the second wafer. The wafer bonding method comprises steps of adding a hydroxyl-ion-containing solution between the first top surface and the second top surface and then applying an external pressure on the first wafer and the second wafer. An annealing process is performed.

According to one embodiment of the present invention, the hydroxyl-ion-containing solution includes a potassium hydroxide solution with a weight percentage of potassium hydroxide in the potassium hydroxide solution of about 2%˜5%.

According to one embodiment of the present invention, the external pressure applied on the first wafer and the second wafer is about 0.4˜2 MPa.

According to one embodiment of the present invention, the external pressure is applied on the first wafer and the second wafer for about 10 min at 70˜100° C.

According to one embodiment of the present invention, the temperature of the annealing process is about 180˜250° C.

According to one embodiment of the present invention, the annealing process is performed for about 2 hours.

According to one embodiment of the present invention, the first wafer further has a trench structure formed therein and a first omni-directional reflector formed on the first top surface and the second wafer further has a second omni-directional reflector formed on the second top surface.

According to one embodiment of the present invention, the first omni-directional reflector and the second omni-directional reflector are comprised of a plurality of first material layer-second material layer pairs respectively.

According to one embodiment of the present invention, the ratio of a first refractive index of the first material layer to a second refractive index of the second material layer is no less than 1.5.

According to one embodiment of the present invention, when the first material layer is the topmost layer on the first wafer and the second wafer, the first material layer is made of amorphous silicon.

According to one embodiment of the present invention, the second material layer is made of silicon oxide.

The present invention further provides a method for manufacturing a hollow optical waveguide. The method comprises steps of providing a first wafer having a trench structure formed therein and a first omni-directional reflector formed thereon and then providing a second wafer having a second omni-directional reflector formed thereon. A wafer bonding process is performed for bonding the first wafer and the second wafer in a manner that the first omni-directional reflector is opposite the second omni-directional reflector so that the trench structure in the first wafer is sealed to form a hollow optical waveguide, wherein a bonding solution is added between the first wafer and the second wafer and an external pressure is applied on the first wafer and the second wafer during the wafer bonding process.

According to one embodiment of the present invention, the bonding solution includes a hydroxyl-ion-containing solution.

According to one embodiment of the present invention, the bonding solution includes a potassium hydroxide solution with a weight percentage of the potassium hydroxide in the dilute potassium hydroxide solution of about 2%˜5%.

According to one embodiment of the present invention, the external pressure applied on the first wafer and the second wafer is about 0.4˜2 MPa.

According to one embodiment of the present invention, the external pressure is applied on the first wafer and the second wafer for about 10 min at 70˜100° C.

According to one embodiment of the present invention, in the step for performing the wafer bonding process further comprises performing an annealing process at about 180˜250° C. for about 2 hours after the external pressure is applied on the first wafer and the second wafer.

According to one embodiment of the present invention, the first omni-directional reflector and the second omni-directional reflector are comprised of a plurality of first material layer-second material layer pairs respectively.

According to one embodiment of the present invention, the ratio of a first refractive index of the first material layer to a second refractive index of the second material layer is no less than 1.5.

According to one embodiment of the present invention, when the first material layer is the topmost layer on the first wafer and the second wafer, the first material layer is made of amorphous silicon.

According to one embodiment of the present invention, the second material layer is made of silicon oxide.

In the present invention, since the first wafer is directly bonding with the second wafer by using the hydroxyl-ion-containing solution as a bonding solution, the air gap at the interface between the first wafer and the second wafer is reduced. Therefore, the propagation efficiency of the hollow optical waveguide using the omni-directional reflector for optical communication application is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart, schematically illustrating a wafer bonding method according to a preferred embodiment of the invention.

FIGS. 2A through 4 are cross-sectional views showing a method for forming a hollow optical waveguide according to one embodiment of the present invention.

### DESCRIPTION OF THE PREFERRED EMBODIMENTS

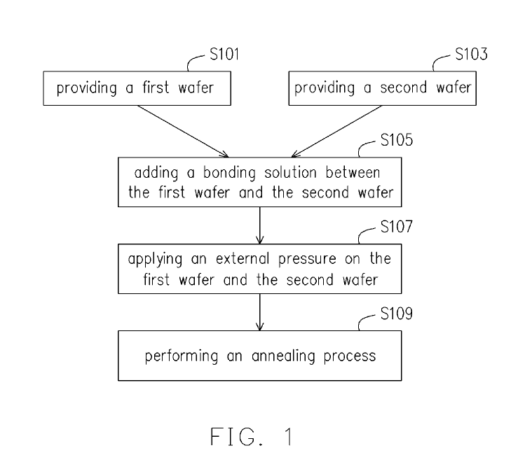

FIG. 1 is a flow chart, schematically illustrating a wafer bonding method according to a preferred embodiment of the invention. As shown in FIG. 1, in the step S101 and the step S103, a first wafer and a second wafer are provided. The first wafer can be, for example, have a first top surface and a trench structure formed in the first top surface. Similarly, the second wafer possesses a second top surface. As for the trench structure in the first wafer, the width of the trench structure can be 3.5˜9 μm and the depth of the trench structure is about 2.0 μm.

In addition, the first wafer further possesses a first omni-directional reflector formed on the first top surface of the first wafer and the second wafer also possesses a second omni-directional reflector formed on the second top surface of the second wafer. Moreover, the first omni-directional reflector and the second omni-directional reflector are composed of several first material layer-second material layer pairs respectively. The material of the first material layer can be, for example, silicon. In addition, the material of the second material layer can be selected from a group consisting of SiO2, GaAs, InP, InAlGaAs and other proper metal oxide. Although both the first material layer and second material layer come from the same list of possible materials, they cannot be identical to each other. In other words, the adjacent alternating first material layer and second material layer must include materials of different refractive indices. When the first material layer is the topmost layer on the first wafer and the second wafer, the ratio of the refractive index of the first material layer to the refractive index of the second material layer is no less than 1.5. In one embodiment, when the first material layer is an amorphous silicon layer and the second material layer is a silicon oxide layer, the thickness of the first material layer is about 0.11 μm and the thickness of the second material layer is about 0.258 μm. Further, the method for forming the first material layer and the second material layer can be, for example but not limited to, a plasma-enhanced chemical vapor deposition performed under 280° C. It should be noticed that the number of the first material layer-second material layer pairs varies and depends on the refraction result of each first material layer-the second material layer pair. Preferably, the number of the first material layer-second material layer pairs on each of the first wafer and the second wafer is six.

In the step S105, the first wafer is bonded with the second wafer in a manner that the first top surface is opposite the second top surface by adding a bonding solution between the first wafer and the second wafer. It should be noticed that the bonding solution can be, for example but not limited to, a hydroxyl-ion-containing solution. Preferably, the bonding solution can be, for example, a potassium hydroxide solution with a weight percentage of the potassium hydroxide in the dilute potassium hydroxide solution of about 2%˜5%. Before the step S105 is performed, a cleaning process can be performed on the first wafer and the second wafer. The cleaning process can be complied with the standard Radio Corporation of America process and performed for 15 min at about 70° C. Then, in the step S107, an external pressure is applied on the first wafer and the second wafer. The external pressure is no less than 0.4 MPa. Preferably, the external pressure is about 0.4˜2 MPa and is applied on the first wafer and the second wafer for about 10 min at a temperature of about 70˜100° C.

Thereafter, in the step S109, an annealing process is performed on the first wafer and the second wafer. The annealing process is performed at about 180˜250° C. for about 2 hours.

In one embodiment, when the topmost layer on each of the first wafer and the second wafer is made of silicon, such as amorphous silicon, the reaction of hydroxyl-ion solution with the silicon in the wafer bonding method according to the present invention is shown as following:

Si+2OH⁻→Si(OH)₂²⁺+4e⁻

That is, the silicon atom at the topmost layer on each of the first wafer and the second wafer is oxidized and the four electrons from each oxidized silicon atom are injected into the conduction band of the silicon. Also, attracted by the positively charged silicon complex, Si(OH)₂²⁺, the electrons remain close to the surface of the surface of the topmost layer, which combines with the Si(OH)₂²⁺ ions to construct an electrolytic dipole layer. These two ions then react with water in the electrolytic layer and undergo the following reaction mechanism:

Si(OH)₂²⁺+4e⁻+4H₂O→Si(OH)₆²⁻+H₂↑

Then, the reaction product, H₂, diffuses along the bonding interface. Therefore, the overall reaction scheme is:

Si+2OH⁻+4H₂O→Si(OH)₆²⁻+H₂↑

Hence, a thin film of Si(OH)₆²⁻, the so-called bonding layer, is formed at the interface between the first wafer and the second wafer. By performing the subsequent external pressing process and annealing process, the bonding layer of Si(OH)₆²⁻ is coalesced with the topmost layer on each of the first wafer and the second wafer and the water and hydrogen gas are removed. The thickness of the thin film of Si(OH)₆²⁻ is about 0.2 μm.

The above embodiment illustrates a wafer bonding method by using the hydroxyl-ion-containing solution according to the present invention. The wafer bonding method can be also applied to the method for manufacturing a hollow optical waveguide. This application is shown in the following embodiment.

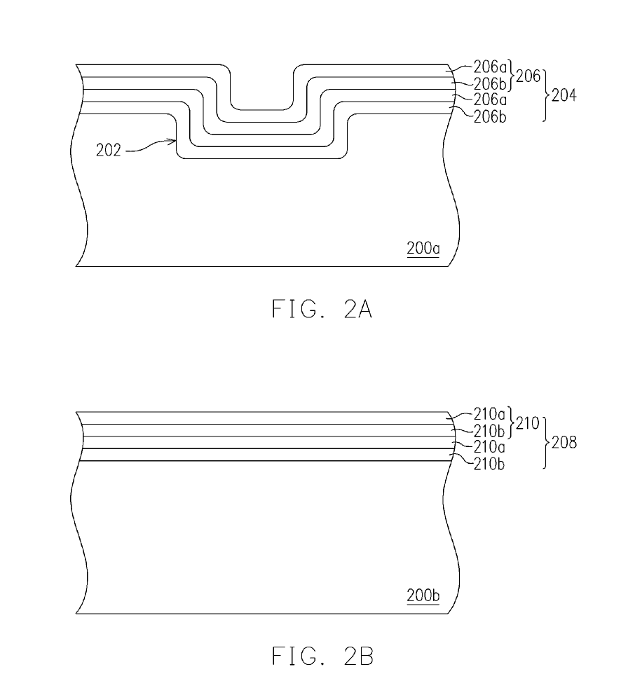

FIGS. 2A through 4 are cross-sectional views showing a method for forming a hollow optical waveguide according to one embodiment of the present invention. As shown in FIG. 2A and FIG. 2B, a first wafer 200a and a second wafer 200b are provided. The first wafer 200a can be, for example, have a trench structure 202 formed therein. The width of the trench structure 202 can be 3.5˜9 μm and the depth of the trench structure 202 is about 2.0 μm. The trench structure 202 can be, for example but not limited to, formed by performing a photolithography process and an inductively coupled plasma etching process to define and etching the first wafer 200a. As shown in FIG. 2a, a first omni-directional reflector 204 is conformally formed on the first wafer 200a. Similarly, a second omni-directional reflector 208 is formed on the second wafer 200b. The method for forming the first omni-directional reflector 204 and the second omni-directional reflector 208 can be, for example, a plasma-enhanced chemical vapor deposition process with an operating temperature of about 280° C. Moreover, the first omni-directional reflector 204 is composed of several first material layer 206a-second material layer 206b pairs 206. Also, the second omni-directional reflector 208 is composed of several third material layer 210a-fourth material layer 210b pairs 210. Preferably, the material of the first material layer 206a can be as same as that of the third material layer 210a and the material of the second material layer 206b can be as same as that of the fourth material layer 210b.

The material of the first material layer 206a/third material layer 210a can be, for example, silicon. In addition, the material of the second material layer 206b/fourth material layer 210b can be selected from a group consisting of Si, SiO2, GaAs, InP, InAlGaAs and other proper metal oxide. Although both the first material layer 206a/third material layer 210a and second material layer 206b/fourth material layer 210b come from the same list of possible materials, they cannot be identical to each other. In other words, the adjacent alternating first material layer 206a/third material layer 210a and second material layer 206b/fourth material layer 210b must include materials of different refractive indices. Preferably, the ratio of the refractive index of the first material layer 206a/third material layer 210a to the refractive index of the second material layer 206b/fourth material layer 210b is no less than 1.5. In one embodiment, when the first material layer 206a/third material layer 210a is an amorphous silicon layer and the second material layer 206b/fourth material layer 210b is a silicon oxide layer, the thickness of the first material layer 206a/third material layer 210a is about 0.111 μm and the thickness of the second material layer 206b/fourth material layer 210b is about 0.258 μm.

Furthermore, the number of the first material layer 206a-second material layer 206b pairs 206 in FIG. 2A is two. However, the number of the first material layer 206a-second material layer 206b pairs 206 of the present invention is not limited to the illustration shown in FIG. 2A. It should be noticed that the number of the first material layer 206a-second material layer 206b pairs 206 varies and depends on the refraction result of each first material layer 206a-the second material layer 206b pair 206. Preferably, the number of the first material layer 206a-second material layer 206b pairs 206 on the first wafer 200a is six. Similarly to the first omni-directional reflector 204, as for the second omni-directional reflector 208, the number of the third material layer 210a-fourth material layer 210b pairs 210 varies and depends on the refraction result of each third material layer 210a-the fourth material layer 210b pair 210. Preferably, the number of the third material layer 210a-fourth material layer 210b pairs 210 on the second wafer 200b is six.

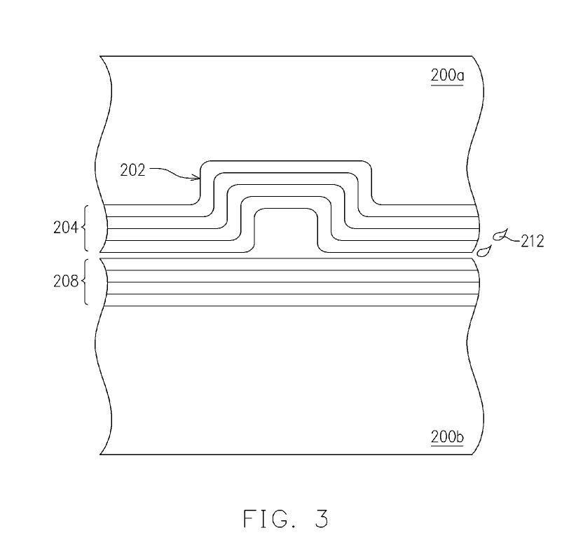

As shown in FIG. 3, the first wafer 200a and the second wafer 200b are bonded in a manner that the first omni-directional reflector 204 is opposite the second omni-directional reflector 208. As the first wafer 200a is bonded with the second wafer 200b, a bonding solution 212 is added at the interface between the first wafer 200a and the second wafer 200b. It should be noticed that the bonding solution 212 can be, for example but not limited to, a hydroxyl-ion-containing solution. Preferably, the bonding solution can be, for example, a potassium hydroxide solution with a weight percentage of the potassium hydroxide in the dilute potassium hydroxide solution of about 2%˜5%.

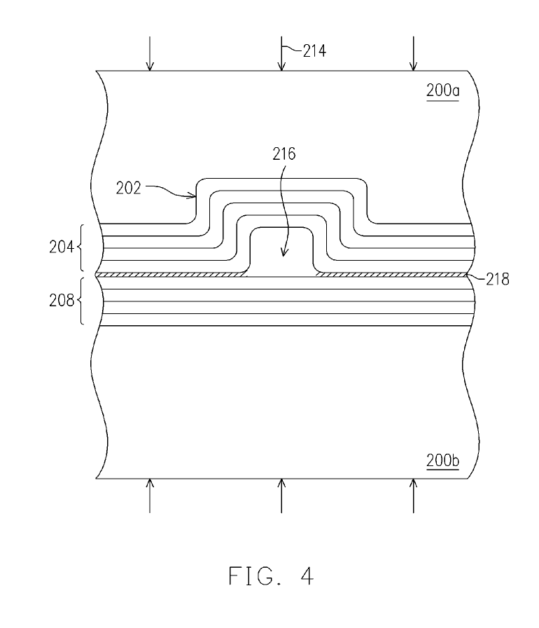

As shown in FIG. 4, an external pressure 214 is applied on the first wafer 200a and the second wafer 200b so that the trench structure 202 in the first wafer 200a is sealed to form a hollow optical waveguide 216. The external pressure is no less than 0.4 MPa. Preferably, the external pressure is about 0.4˜2 MPa and is applied on the first wafer and the second wafer for about 10 min at a temperature of about 70˜100° C. Therefore, a thin film 218 is formed at the interface between the first wafer 200a and the second wafer.

Then, an annealing process is performed on the first wafer 200a and the second wafer 200b. The annealing process is performed at about 180˜250° C. for about 2 hours.

As stated in the previous embodiment, the hydroxyl ions in the bonding solution are reacted with the first material layer 206a and the third material layer 210a respectively to form the thin film 218 and the detail reaction procedure is not described herein. Furthermore, preferably, when both of the first material layer and the third material layer are made of amorphous silicon and the bonding solution is the potassium hydroxide solution, the thickness of the thin film is about 0.2 μm.

By measuring the transmittance spectra versus the wavelength by using a broad-band light source connected to an single mode fiber and directly coupled into the hollow optical waveguide with an objective lens (20×), the propagation loss by using the hollow optical waveguide formed by using the method according to the present invention is about 1.0±0.3 and 1.0±0.4 dB/cm for TE and TM modes respectively. By comparing with the hollow optical waveguide having expoxy as the attach medium, which possesses the propagation loss about 1.7 dB/cm, the propagation loss of the hollow optical waveguide of the present invention is much smaller.

By directly bonding the first wafer and the second wafer with the use of the hydroxyl-ion-containing solution, the air gap at the interface between the first wafer and the second wafer is reduced and the propagation efficiency of the hollow optical waveguide using the omni-directional reflector for optical communication application is improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A wafer bonding method for bonding a first wafer with a second wafer, wherein the first wafer has a first top surface and the second wafer has a second top surface formed thereon and the first wafer bonds with the second wafer in a manner that the first top surface of the first wafer is opposite the second top surface of the second wafer, the wafer bonding method comprising:
adding a hydroxyl-ion-containing solution between the first top surface and the second top surface;
applying an external pressure on the first wafer and the second wafer; and
performing an annealing process.

2. The wafer bonding method of claim 1, wherein the hydroxyl-ion-containing solution includes a potassium hydroxide solution with a weight percentage of potassium hydroxide in the potassium hydroxide solution of about 2%˜5%.

3. The wafer bonding method of claim 1, wherein the external pressure applied on the first wafer and the second wafer is about 0.4˜2 MPa.

4. The wafer bonding method of claim 1, wherein the external pressure is applied on the first wafer and the second wafer for about 10 min at 70˜100° C.

5. The wafer bonding method of claim 1, wherein the temperature of the annealing process is about 180˜250° C.

6. The wafer bonding method of claim 1, wherein the annealing process is performed for about 2 hours.

7. The wafer bonding method of claim 1, wherein the first wafer further has a trench structure formed therein and a first omni-directional reflector formed on the first top surface and the second wafer further has a second omni-directional reflector formed on the second top surface.

8. The wafer bonding method of claim 7, wherein the first omni-directional reflector and the second omni-directional reflector are comprised of a plurality of first material layer-second material layer pairs respectively.

9. The wafer bonding method of claim 8, wherein the ratio of a first refractive index of the first material layer to a second refractive index of the second material layer is no less than 1.5.

10. The wafer bonding method of claim 8, wherein, when the first material layer is the topmost layer on the first wafer and the second wafer, the first material layer is made of amorphous silicon.

11. The wafer bonding method of claim 10, wherein the second material layer is made of silicon oxide.

12. A method for manufacturing a hollow optical waveguide, comprising:
providing a first wafer having a trench structure formed therein and a first omni-directional reflector formed thereon;
providing a second wafer having a second omni-directional reflector formed thereon;
performing a wafer bonding process for bonding the first wafer and the second wafer in a manner that the first omni-directional reflector is opposite the second omni-directional reflector so that the trench structure in the first wafer is sealed to form a hollow optical waveguide, wherein a bonding solution is added between the first wafer and the second wafer and an external pressure is applied on the first wafer and the second wafer during the wafer bonding process.

13. The method of claim 12, wherein the bonding solution includes a hydroxyl-ion-containing solution.

14. The method of claim 13, wherein the bonding solution includes a potassium hydroxide solution with a weight percentage of the potassium hydroxide in the dilute potassium hydroxide solution of about 2%˜5%.

15. The method of claim 12, wherein the external pressure applied on the first wafer and the second wafer is about 0.4˜2 MPa.

16. The method of claim 12, wherein the external pressure is applied on the first wafer and the second wafer for about 10 min at 70˜100° C.

17. The method of claim 12, wherein, in the step for performing the wafer bonding process further comprises performing an annealing process at about 180˜250° C. for about 2 hours after the external pressure is applied on the first wafer and the second wafer.

18. The method of claim 12, wherein the first omni-directional reflector and the second omni-directional reflector are comprised of a plurality of first material layer-second material layer pairs respectively.

19. The method of claim 18, wherein the ratio of a first refractive index of the first material layer to a second refractive index of the second material layer is no less than 1.5.

20. The method of claim 18, wherein, when the first material layer is the topmost layer on the first wafer and the second wafer, the first material layer is made of amorphous silicon.

21. The wafer bonding method of claim 18, wherein the second material layer is made of silicon oxide.
